(19) United States
(12) Patent Application Publication
(10) Pub. No.: US 2011/0274838 A1
(43) Pub. Date: Nov. 10, 2011

(54) SYSTEM AND PROCESS FOR THE CONTINUOUS VACUUM COATING OF A MATERIAL IN WEB FORM

(75) Inventors: Francisco Villuendas Yuste, Zaragoza (ES); Rafael Alonso Esteban, Huesca (ES); Inigo Salinas Ariz, Zaragoza (ES); Gerardo Hidalgo Llinas, Cartagena (ES)

(73) Assignee: NOVOGENIO, S.L., CARTAGENA (ES)

(21) Appl. No.: 12/674,233

(22) PCT Filed: Aug. 5, 2008
(86) PCT No.: PCT/EP08/60278

§ 371 Date: Feb. 19, 2010

(30) Foreign Application Priority Data
Aug. 20, 2007 (ES) P 200702303

(51) Int. Cl. C23C 16/54; C23C 16/50; C23C 16/02; C23C 14/35; C23C 16/52; C23C 16/44; C23C 16/06; C23C 14/34; C23C 16/458; C23C 16/56

(52) U.S. Cl. 427/251; 118/715; 118/724; 118/723 R; 118/719; 118/33; 118/665; 427/255.5; 204/298.02; 204/298.16

(57) ABSTRACT

The system (1) for the continuous vacuum coating of a continuously suppliable material in web form (2) provided with feed means; at least one inlet chamber (4), wherein the transition between the inlet atmospheric pressure and the vacuum pressure of a coating chamber (5) incorporating at least one vacuum deposition module (6) for depositing metallic and/or dielectric components on the material in web form is carried out; at least one outlet chamber (7); and collecting means (8) which collect the coated material in web form. The system further comprises drive and support means (9), on which the material in web form is fixed for its transport and by one of its faces, which material follows a preferably straight path at least through the coating chamber.

### TECHNICAL FIELD OF THE INVENTION

The present invention relates to a system and a process for the continuous vacuum coating of continuously suppliable materials in web form, such as laminas, films or sheets.

### BACKGROUND OF THE INVENTION

Plastic materials have undergone an important development due to the appearance of new products and technical innovations for obtaining them. This has in turn allowed these products to improve their properties and extend their scopes of application. Thus, in some cases, traditional materials such as glass and even steel have been replaced by plastic materials.

Due to their structural properties, polymeric materials generally offer advantages over metals as regards mouldability, transformation, weight, maintenance and stability against oxidation processes. Even so, they have limitations such as their hardness, abrasion resistance, heat resistance and mechanical consistency.

A usual process which has normally been used to compensate for these drawbacks is that of protecting them by means of the application of different types of chemical or physical treatments. They are surface coating processes also known as coating. In some cases, surprising results have been achieved by means of these types of treatments which allow manufacturing plastic materials with a high mechanical performance.

Other types of coatings which are usually applied on plastic materials are multilayer optical coatings deposited by PVD (Physical Vapor Deposition) techniques in vacuum conditions. These coatings furthermore confer specific optical properties to the plastic materials.

There are several options for the coating of the material in lamina or web form, whether or not it is a polymeric material. One of them corresponds to the technique called air-to-air, in which the material enters the deposition chamber from atmospheric pressure through a preparatory vacuum chamber, as is described in document GB2084264. The advantage of this technique is that the winding and unwinding are carried out at atmospheric pressure, but its drawback is that it is only valid for hard materials as is the case of metallic substrates.

Another technique more specifically oriented to the coating of materials in web form, as is the case of plastic films, laminas, sheets or webs, is that described in document WO03/046251. According to this technique, the winding and unwinding chamber must be in vacuum conditions, therefore the loading, unloading and threading of the system involves breaking the vacuum. Furthermore, the number of deposition systems that it can incorporate is very limited.

The need to treat plastic materials in order to improve their surface properties, especially some optical, chemical and abrasion resistance properties, is known. Other properties, such as the oxygen barrier effect and moisture resistance can be improved if the plastic materials are subjected to special treatments. Many of these coating processes are carried out by means of vacuum PVD techniques. Applying these coatings on soft materials in web form, such as polymeric films or laminas has a number of difficulties. One of these difficulties is due to the need for the winding and the unwinding to be carried out in vacuum conditions (WO03/046251). This means that it is necessary to break the vacuum for the processes for loading, unloading and threading the film, with the subsequent loss of efficiency of the installation, since the processes for breaking and especially for re-obtaining the vacuum require long time periods. Another drawback is given by the fact that the materials in web form are slid and driven by means of rollers and tensioners. This means that the material in web form is subjected to tension and said tension leads to deformation problems.

Another important fact is that as the material in web form is supported by rollers, the length of material subjected to coating, and therefore the number of treatments to which such material can be subjected as well, is limited. Furthermore, this problem is enhanced in the case of materials in web form such as polymeric laminar materials because in certain deposition processes, such as for example in the sputtering process, the plastic material is electrostatically charged. This phenomenon causes the appearance of forces tending to displace the material in a direction parallel to the movement, which leads to the increase of the tension for preventing said movement.

Another drawback of the methods for coating laminar materials or polymeric films carried out under vacuum is that the designs or configurations thereof do not allow treatments before and after the deposition process, given the difficulty of applying these types of treatments in vacuum conditions.

Finally, another drawback occurs when the deposition process is carried out from the upper part of a material in web form because all the remains of the deposition process fall by gravity on the material to be coated, which causes defects in the coating that seriously affect the quality of the product, the quality of the production and the profitability of the production processes.

Taking into account all the mentioned problems, a system and a process for the continuous vacuum coating of a material in web form is disclosed which overcomes the drawbacks of the state of the art.

### DISCLOSURE OF THE INVENTION

The object of the present invention is a system for the continuous vacuum coating of a continuously suppliable material in web form which allows a large number of treatments. Said system is formed by at least:

a) feed means supplying the material in web form to be coated;

b) at least one inlet chamber, in which the material in web form to be coated is introduced and wherein the transition between the inlet atmospheric pressure and the vacuum pressure of an adjacent coating chamber is carried out;

c) a coating chamber incorporating at least one vacuum deposition module for the deposition of metallic and/or dielectric components on the material in web form;

d) at least one outlet chamber, in which the transition between the vacuum pressure of the adjacent coating chamber and the atmospheric pressure is carried out; and

e) collecting means which collect the coated material in web form.

For the purpose of solving the problems of the state of the art, the system object of the invention is essentially characterized in that it further comprises drive and support means on which the material in web form is fixed for its transport and by one of its faces, at least through the coating chamber.

A material in web form must be understood in the context of the present invention as any material with a polymeric or non-polymeric base which can be continuously supplied to the system. This refers to laminas, films or sheets, i.e., to continuous or discontinuous units to be treated by means of the system and process described in this invention. Thus, in the context of the present invention, a material in web form must be understood as any type of paper, fabric, film or lamina suitable for being continuously supplied to a coating chamber, for example by means of feed reels. It is evident that when the material in web form consists of independent sheets of any nature, it is understood that means are provided so that these sheets can be continuously supplied.

A lamina can in turn be defined as a thin web of any material, which is also called film if it can be wound. In any case, the expressions laminar material, lamina or film are used without distinction in the present invention.

According to another feature of the invention, the system for the vacuum coating of a material in web form comprises drive and support means. Together with such means, the material in web form follows a vertically oriented straight path through the coating chamber.

Alternatively, the system object of the invention is arranged such that the drive and support means, and with them the material in web form, follow a horizontally oriented straight path through the coating chamber.

The system object of the invention, and in a horizontal position, is also characterized in that the vacuum deposition module is located below and opposite to the free face of the material in web form.

According to another aspect of the invention, the vacuum deposition module is located such that the coating takes place directly on the material in web form and is applied thereon in the direction perpendicular to the forward movement direction of the drive and support means and, therefore, to the direction of said material in web form.

The system according to the invention is characterized in that the deposition module is selected from the different deposition techniques, namely: physical vapor deposition (PVD) technique deposition modules, chemical vapor deposition (CVD) technique deposition modules, heat deposition modules, electron gun deposition modules, sputtering or ion implantation technique deposition modules and plasma treatment deposition modules.

The system can comprise multiple modules of the same type or nature or, alternatively, the deposition modules of the coating chamber can be several and of different natures or types.

A system comprising at least one sputtering or ion implantation technique deposition module including more than one magnetron is preferred.

The system object of the invention is characterized in that the drive and support means are preferably formed by at least one endless conveyor belt, on which the material in web form is applied and together with which the mentioned material in web form moves forward in an integral manner, at least along the coating chamber.

According to another feature of the invention, the endless conveyor belt is coated with a polymeric adhesive lamina, on which the material in web form is detachably applied by means of a heat adhesion process.

The system according to the invention is also characterized in that the polymeric adhesive lamina comprises at least one compound selected from the group consisting of polyolefins, EVA (ethylene-vinyl acetate), polyurethanes, PVB or acrylics or copolymers thereof.

According to another feature of the invention, the system is provided with mechanical pulling means for pulling the material in web form arranged close to the outlet chamber and suitable for separating the already coated material in web form from the drive and support means.

The system object of the invention is also characterized in that the drive and support means are coated with an adhesive skin on which the material in web form is fixed by means of a contact process and/or a heat adhesion process.

It is also an object of the present invention that the system uses a material in web form, such as a film on at least one of the faces of which adhesive has been applied and suitable for being fixed directly to the drive and support means.

According to another feature of the system object of the invention, the feed means are formed by an unwinding device; and the collecting means are formed by a winding device.

The system according to the invention is characterized in that the inlet chamber and the outlet chamber comprise multiple compartments provided with a plurality of vacuum pumps.

According to another aspect of the invention, the system comprises tension control means between the feed means and the drive and support means; and between the drive and support means and the collecting means.

The system according to the invention is characterized in that it comprises optical control means for the deposited coating and which would be located at the exit of the drive and support means.

The system according to the invention is also characterized in that it comprises at least one pressure roller causing the coupling between the material in web form and the drive and support means.

The system according to the invention is characterized in that it comprises pre-treatment and/or post-treatment stations located respectively before or after the vacuum deposition module.

According to another feature of the invention, the pre-treatment station consists of a protective lamina extraction station.

Alternatively and also according to the invention, the pre-treatment station consists of a lamination coating station.

The system according to the invention is characterized in that the pre-treatment station consists of a deposition station for depositing protective layers by spraying and/or roller techniques.

According to another feature of the invention, the system comprises a post-treatment station consisting of a coating station for coating with a protective layer by means of the adhesion thereof to the material in web form and/or by hotmelt techniques.

Alternatively, the post-treatment station consists of a lamination coating station.

Alternatively, the system comprises a post-treatment station consisting of a deposition station for depositing protective layers by spraying and/or roller techniques.

The system according to the invention is characterized in that the material in web form is in lamina, film or sheet form.

The material in web form is preferably a polymeric film.

Another object of the invention is a process for the vacuum coating of a material in web form comprising a coating step in which at least one vacuum deposition operation for depositing metallic and/or dielectric components is carried out; and characterized in that in the coating step, the material in web form is driven and supported in a linear direction to vacuum deposition modules for depositing metallic and/or dielectric components.

The process according to the invention is characterized in that the material in web form is driven and supported in a linear direction to a plurality of means for adjusting the mentioned material to the working pressures, from an adjustment step for adjusting the mentioned material to the vacuum pressure, optimal for its coating, until a suitable outlet step for returning the material in web form to the usual atmospheric pressure.

According to another feature of the invention, the process for the vacuum coating of a material in web form further comprises pre-treatment and/or post-treatment steps for said material in web form.

### BRIEF DESCRIPTION OF THE DRAWINGS

The attached drawings show, by way of a non-limiting example, an embodiment of the system object of the invention. In said drawings:

FIG. 1 is a schematic representation of the system according to the invention by means of which the process object of such invention is carried out.

### DETAILED DESCRIPTION OF THE DRAWINGS

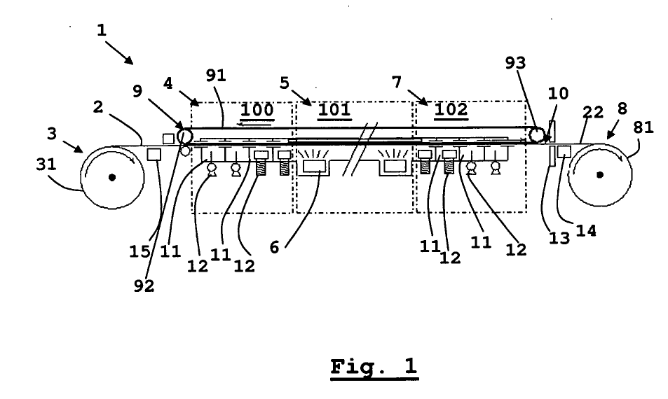

The system 1 for the vacuum coating of a material in web form 2, such as a film, a lamina, a cloth, paper, which is continuous or discontinuous, such as a plurality of sheets and as shown in FIG. 1, comprises feed means 3; an inlet chamber 4; a coating chamber 5 incorporating a plurality of vacuum deposition modules 6; an outlet chamber 7; and collecting means 8.

The feed means 3 supply the material in web form 2 to be coated, a material in film or lamina form in the case shown, and the collecting means 8 collect the coated material in web form 22. The mentioned feed means 3 and the mentioned collecting means 8 are formed by an unwinding device 31 and a winding device 81, respectively.

The inlet chamber 4, in which the material in web form 2 to be coated is introduced, carries out the transition between the inlet atmospheric pressure and the vacuum pressure of the coating chamber 5. In addition, the outlet chamber 7 carries out the transition between the vacuum pressure of the coating chamber 5 and the outlet atmospheric pressure of the coated material in web form 22. The mentioned inlet chamber 4 and the mentioned outlet chamber 7 use the system known as air-to-air to adjust the working pressures. Both chambers (4, 7), which are symmetrical, have multiple compartments 11 provided with a plurality of vacuum pumps 12, in which the adjustment of the working pressure is carried out both in the feed and the unloading, there being air and preventing the breaking of the vacuum. Normally, vacuum loading and unloading chambers are required for vacuum treatments, such that a perfect operation of the system is ensured, high vacuums being reached in the deposition chambers. In this case, to reach and regulate the vacuums required in the coating chamber 5, pumps with different pumping and vacuum capacity (for example, high air-pumping capacity and low vacuum pumps and high vacuum capacity pumps; and between which there are other intermediate pumps) are used such that the vacuum is progressively reached by means of medium or low vacuum pumps, mainly mechanical, rotary and Roots pumps, and high vacuum pumps, such as diffuser, turbomolecular or cryogenic pumps.

The vacuum deposition modules 6 of the coating chamber 5 carry out the vacuum deposition of metallic and dielectric components on the material in web form 2 to be coated. The different techniques used for the deposition are physical vapor deposition, known as PVD; heat deposition; the deposition carried out by means of electron guns; sputtering or ion implantation; chemical vapor deposition, known as CVD, or plasma treatment. Several sputtering chambers can also be used, each of them including several magnetrons. Many other techniques are also possible and applicable for achieving the deposition of the desired materials.

The system 1 further comprises drive and support means 9 which are in charge of supplying the material in web form 2, for example a material in a continuous polymeric material lamina form, to be coated in the coating chamber 5. The mentioned drive and support means 9 on which the material in web form 2 is fixed for its transport and by one of its faces, are arranged such that said material in web form 2 ends up describing a straight path at least through the coating chamber 5.

As deduced from FIG. 1, the vacuum deposition modules 6 of the coating chamber 5 are located below the material in web form 2 and opposite to the free or exposed face thereof which is not in contact with the drive and support means 9. A distribution of this type facilitates carrying out a process for the vacuum coating of polymeric or non-polymeric materials in web form 2, which can operate continuously and which allows a high number of treatments. In the case shown, the material in web form 2 is fixed to the drive and support means 9 at the entrance of the inlet chamber 4 and extracted at the exit of the outlet chamber 7.

In the system 1 shown in FIG. 1, the vacuum deposition modules 6 are located such that the coating takes place directly on the material in web form 2 and is applied thereon in the direction perpendicular to the forward movement direction of the drive and support means 9. With a configuration of this type, the possible remains of the deposition process are advantageously prevented from falling by gravity on the material in web form 2 to be coated, which causes heterogeneity in the coating, significantly affecting the quality of the production and the profitability and efficiency of the total coating process.

Said drive and support means 9 are formed by an endless conveyor belt 91, on which the material in web form 2 is applied. This endless conveyor belt 91 is metallic, mainly made of steel or aluminium, and is driven by means of two rollers (92, 93), one of them being a drive roller, which incorporate guiding mechanisms to prevent the lateral displacement of the endless conveyor belt 91. The material in web form to be coated 2 moves forward in an integral manner together with the mentioned endless conveyor belt 91, at least inside the coating chamber 5. According to other possible variants, the conveyor belt is elastomeric or is formed from the combination of polymeric materials with inorganic products complying with the mechanical properties and thicknesses suitable for being used as conveyor surfaces.

In a preferred embodiment, the endless conveyor belt 91 is coated with a polymeric adhesive film (not shown), on which the material in web form 2 is detachably fixed by means of a heat adhesion process. The mentioned polymeric adhesive lamina comprises a polyolefin compound selected from the group consisting of EVA (ethylene-vinyl acetate) or polyhexene. In addition, it is also provided that it is a polymeric adhesive lamina comprised by other compounds such as those selected from the group of polyurethanes, PVB, acrylics or TPU. The heat adhesion process for fixing the material in web form 2 to the polymeric adhesive lamina is carried out by pre-heating, by means of a heating system, the mentioned polymeric adhesive lamina 92 between 30° C. and 130° C. As a whole, a pressure roller 15 is provided which causes the coupling between the material in web form 2 and the drive and support means 9.

The temperature reached and the pressure exerted have to be suitable for ensuring the adherence of the material in web form 2 during the deposition process in the coating chamber 5, but at the same time for allowing the detachment thereof by mechanical pulling after the vacuum coating process has ended.

In the system 1 according to the invention, a cooling system in the drive and support means 9 is preferably provided, located inside the coating chamber 5 and preventing excessive increases of the temperature of the material in web form 2. Said cooling system consists of a cooling water conduction system in contact with or close to the endless conveyor belt 91, such that they exchange heat by radiation and/or conduction. Furthermore, they can incorporate systems for eliminating the static electricity in the drive and support means 9 by means of rollers electrically connected to earth in contact with the endless conveyor belt 91.

In addition to being able to carry out at least the coating step, the system can comprise subsystems or stations in which the pre-treatment and post-treatment steps for the material in web form 2 and for the coated film or soft material 22 are carried out. Thus, it is provided that in a pre-treatment step a protective lamina provided for that purpose in the material in web form 2 can be removed by means of a lamination process (adhesion of several films to improve it properties or by means of a surface treatment process of other materials by spray or roller techniques). Alternatively, in a post-treatment step, a protective lamina can be placed by adhesion or hotmelt techniques, as well as the lamination or the deposition of protective layers on the coated soft material 22 by spray or roller type techniques.

In another variant, not shown, the drive and support means 9 are coated with an adhesive skin (not shown), on which the chosen material in web form 2 is fixed by means of a contact process or a heat adhesion process.

In another variant, also not shown, the material in web form 2, which can have in this case adhesive properties (by contact or temperature) on both faces, has adhesive applied on one of its faces to be fixed directly to the drive and support means 9, and on the other face to facilitate the fixing of the materials to be deposited.

Furthermore, for the purpose of controlling at all times the tension of the material in web form 2, the system 1 is provided with tension control means 13 between the feed means 3 and the drive and support means 9; and between the drive and support means 9 and the collecting means 8.

The control of the quality of the coating of the material in web form 2 is carried out in the system 1 by means of optical control means 14 for controlling the deposited coating provided at the exit of the drive and support means 9.

As regards the working order or process of the system 1, it must be mentioned that the process for the vacuum coating of a material in web form 2 comprises the following steps:
A feeding step which by means of the feed means 3 is in charge of supplying the material in web form 2 intended to be treated;
An adjustment step 100 in which the initial atmospheric pressure with which the material in web form 2 arrives is progressively changed to the optimal vacuum pressure for its coating;
A coating step 101 carrying out the coating of the material in web form 2 by means of multiple vacuum deposition operations for depositing metallic and dielectric components;
An outlet step 102 carrying out the reverse process to the adjustment step 100, i.e., it progressively changes the vacuum pressure of the material in web form 2 to the outlet atmospheric pressure of the coated laminar material 22; and
A collection step which collects and stores the coated soft material 22.

Notably, in the coating step 101, the material in web form 2 is driven and supported in a linear direction to the vacuum deposition modules 6 for depositing metallic and dielectric components. Specifically, the direction of the deposition is perpendicular to the forward movement of the material in web form 2 in the system 1 and in a down (where the vacuum deposition modules 6 are located) to up (where the laminar material 2 fixed to the drive and support means 9 is located) direction.

As has been described above, it is especially important to be able to include pre-treatment and post-treatment steps for the soft material (2, 22) in the process. In these steps, the possibility is contemplated of laminating or adding additives in the laminar material 2 before a metallic or dielectric component is deposited in it; or of the coated soft, material 22 being sprayed with any composition of interest intended, for example, to protect the mentioned material 22 in which a metallic component has been deposited.

It is especially preferred to be able to work with the previously described air-to-air technique because it facilitates that these pre- and post-treatment steps or stations can be carried out continuously like the coating step (101) by the vacuum deposition of metallic and/or dielectric components, without, therefore, interrupting any step of the process, making it more complete and increasing its efficiency.

In the event that the material in web form 2 consists of a plurality of discontinuous sheets or laminas, means are provided so that they can be continuously supplied to the system, specifically in the coating chamber 5. Thus, a plurality of independent and separable sheets arranged on a continuous film suitable for being wound, or means for dispensing said independent units of sheets which are continuously introduced in the coating chamber 5 can be considered.

Having sufficiently described the system 1 and process for the vacuum coating of a material in web form 2, it is evident that any modification in relation to the number or type of pre- or post-treatment stations, number or type of deposition modules 6, feed means 3 and collecting means 8, drive and support means 9, also form part of the object of the present invention.

1. A system (1) for the continuous vacuum coating and subsequent supply of a material in web form (2) comprising:
a) feed means (3) supplying the material in web form to be coated;
b) at least one inlet chamber (4), in which the material in web form to be coated is introduced and wherein the transition between the inlet atmospheric pressure and the vacuum pressure of a coating chamber (5) is carried out;
c) the coating chamber incorporating at least one vacuum deposition module (6) for the deposition of metallic and/or dielectric components on the material in web form;
d) at least one outlet chamber (7), in which the transition between the vacuum pressure of the coating chamber and the atmospheric pressure is carried out; and
e) collecting means (8) which collect the coated material in web form;
characterized in that it further comprises drive and support means (9), on which the material in web form is fixed for its transport and by one of its faces, at least through the coating chamber.

2. The system (1) for the vacuum coating according to claim 1, characterized in that the drive and support means (9) and with them the material in web form (2) follow a vertically oriented straight path in the coating chamber.

3. The system (1) for the vacuum coating according to claim 1, characterized in that the drive and support means (9) and with them the material in web form (2) follow a horizontally oriented straight path in the coating chamber.

4. The system (1) according to claim 3, characterized in that the vacuum deposition module (6) is located below and opposite to the exposed face of the material in web form (2).

5. The system (1) according to any one of the previous claims, characterized in that the vacuum deposition module (6) is located such that the coating takes placed directly on the material in web form (2) and is applied thereon in the direction perpendicular to the forward movement direction of the drive and support means (9) and, therefore, of said material in web form.

6. The system (1) according to any one of the previous claims, characterized in that the deposition module (6) is independently selected from the group consisting of physical vapor deposition (PVD) technique deposition modules, chemical vapor deposition (CVD) technique deposition modules, heat deposition modules, electron gun deposition modules, sputtering or ion implantation technique deposition modules and plasma treatment deposition modules.

7. The system (1) according to any one of claims 1 to 6, characterized in that it comprises multiple deposition modules (6) of the same type.

8. The system (1) according to any one of claims 1 to 6, characterized in that it comprises multiple deposition modules (6) of a different nature.

9. The system (1) according to any one of the previous claims, characterized in that it comprises at least one sputtering or ion implantation technique deposition module (6) including more than one magnetron.

10. The system (1) according to any one of the previous claims, characterized in that the drive and support means (9) are formed by at least one endless conveyor belt (91), on which the material in web form (2) is applied and together with which the mentioned material in web form moves forward at least along the coating chamber (5).

11. The system (1) according to claim 10, characterized in that the endless conveyor belt (91) is coated with a polymeric adhesive lamina, on which the material in web form is detachably fixed by means of a heat adhesion process.

12. The system (1) according to claim 11, characterized in that the polymeric adhesive lamina comprises at least one compound selected from the group consisting of polyolefins, EVA (ethylene-vinyl acetate), polyurethanes, PVB or acrylics or copolymers thereof.

13. The system (1) according to any one of the previous claims, characterized in that it is provided with mechanical pulling means (10) for pulling the material in web form, arranged close to the outlet chamber (7), suitable for separating the already coated material in web form (22) from the drive and support means (9).

14. The system (1) according to any one of the previous claims, characterized in that the drive and support means (9) are coated with an adhesive skin, on which the material in web form (2) is detachably fixed by means of a contact process and/or a heat adhesion process.

15. The system (1) according to any one of the previous claims, characterized in that the material in web form (2) has adhesive applied on at least one of its faces and is suitable for being fixed directly to the drive and support means (9).

16. The system (1) according to any one of the previous claims, characterized in that the feed means (3) are formed by an unwinding device (31); and the collecting means (8) are formed by a winding device (81).

17. The system (1) according to any one of the previous claims, characterized in that the inlet chamber (4) and the outlet chamber (7) comprise multiple compartments (11) provided with a plurality of vacuum pumps (12).

18. The system (1) according to any one of the previous claims, characterized in that it comprises tension control means (13) between the feed means (3) and the drive and support means (9), and between the drive and support means and the collecting means (8).

19. The system (1) according to any one of the previous claims, characterized in that it comprises optical control means (14) for controlling the deposited coating, arranged at the exit of the drive and support means (9).

20. The system (1) according to any one of the previous claims, characterized in that it comprises at least one pressure roller (15) causing the coupling between the material in web form (2) and the drive and support means (9).

21. The system (1) according to any one of the previous claims, characterized in that it comprises pre-treatment and/or post-treatment stations located respectively before or after the vacuum deposition module (6).

22. The system (1) according to claim 21, wherein the pre-treatment station consists of a protective lamina extraction station.

23. The system (1) according to claim 21, wherein the pre-treatment station consists of a lamination coating station.

24. The system (1) according to claim 21, wherein the pre-treatment station consists of a deposition station for depositing protective layers by spraying and/or roller techniques.

25. The system (1) according to claim 21, wherein the post-treatment station consists of a coating station for coating with a protective layer by means of the adhesion thereof to the laminar material (22) and/or by hotmelt techniques.

26. The system (1) according to claim 21, wherein the post-treatment station consists of a lamination coating station.

27. The system (1) according to claim 21, wherein the post-treatment station consists of a deposition station for depositing protective layers by spraying and/or roller techniques.

28. The system (1) according to any one of the previous claims, characterized in that the material in web form (2) is in lamina, film or sheet form.

29. The system (1) according to any one of the previous claims, characterized in that the material in web form (2) is a polymeric film.

30. A process for the vacuum coating of a material in web form (2) comprising
a coating step (101) in which at least one vacuum deposition operation for depositing metallic components is carried out;
characterized in that, in the coating step, the material in web form is driven and supported in a linear direction to vacuum deposition modules (6) for depositing metallic and/or dielectric components.

31. The process according to the previous claim, characterized in that the material in web form (2) is driven and supported in a linear direction to a plurality of means for adjusting the material in web form to the working pressures, from an adjustment step (100) for adjusting the material in web form to the vacuum pressure, optimal for its coating, until a suitable outlet step (102) for returning the material in web form to the usual atmospheric pressure.

32. The process for the vacuum coating of a material in web form (2) according to any one of claims 30 to 31, characterized in that it further comprises pre-treatment and/or post-treatment steps for the material in web form (2, 22).
